(19) United States
(12) Patent Application Publication
(10) Pub. No.: US 2008/0315338 A1
(43) Pub. Date: Dec. 25, 2008

(54) IMAGE SENSOR AND METHOD FOR MANUFACTURING THE SAME

(76) Inventor: IN GUEN YEO, Eumseong-gun (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 12/141,140

(22) Filed: Jun. 18, 2008

(30) Foreign Application Priority Data
Jun. 22, 2007 (KR) 10-2007-0061465

(51) Int. Cl. H01L 27/14; H01L 21/00

(52) U.S. Cl. 257/431; 438/70; 257/E27.133; 257/E27.141

(57) ABSTRACT

Disclosed are an image sensor and a method for manufacturing the same. The image sensor can include a substrate with a photodiode formed thereon. A metal interconnection and interlayer dielectric layer can be formed on the substrate, the interlayer dielectric layer having a recess structure formed by selectively removing a region of the interlayer dielectric layer corresponding to the photodiode. A clad layer can be provided on the interlayer dielectric layer, including along the walls and bottom of the recess structure, and a core layer can be formed on the clad layer.

### CROSS-REFERENCE TO RELATED APPLICATION

The present application claims the benefit under 35 U.S.C. §119 of Korean Patent Application No. 10-2007-0061465, filed Jun. 22, 2007, which is hereby incorporated by reference in its entirety.

### BACKGROUND

In general, image sensors are semiconductor devices that convert optical images into electrical signals. Image sensors are mainly classified as a charge coupled device (CCD) or a complementary metal oxide semiconductor (CMOS) image sensor (CIS).

The CIS includes a photodiode and a MOS transistor in each unit pixel, and sequentially detects the electric signals of each unit pixel in a switching mode to realize images.

As the pixel size is reduced, and a multilayer metal is used, the CMOS image sensor has problems related to crosstalk and the degradation of sensitivity derived from optical scattering.

The crosstalk can induce an image lagging. Crosstalk refers to a phenomenon in which adjacent pixels are affected by light directed incorrectly to the pixel due to diffraction, interference, or focusing of light. In addition, the degradation of sensitivity can cause problems related to a low illumination characteristic.

### BRIEF SUMMARY

Embodiments of the present invention provide an image sensor and a method for manufacturing the same, capable of addressing problems related to crosstalk.

In addition, an embodiment of the present invention provides an image sensor and a method for manufacturing the same, capable of increased sensitivity.

An image sensor according to an embodiment includes a photodiode on a substrate; a metal interconnection and an interlayer dielectric layer on the substrate, the interlayer dielectric layer having a recess structure in a region corresponding to the photodiode; a clad layer on the interlayer dielectric layer; and a core layer on the clad layer.

A method for manufacturing an image sensor according to an embodiment, includes forming a photodiode on a substrate, forming a metal interconnection and an interlayer dielectric layer on the substrate, forming a recess structure by selectively removing the interlayer dielectric layer in a region corresponding to the photodiode, forming a clad layer on the interlayer dielectric layer having the recess structure, forming a core layer on the clad layer, and forming a color filter layer on the core layer.

### BRIEF DESCRIPTION OF THE DRAWINGS

FIG. 1 is a cross-sectional view showing an image sensor according to an embodiment of the present invention.

FIGS. 2 to 5 are cross-sectional views for describing a method for manufacturing an image sensor according to an embodiment of the present invention.

### DETAILED DESCRIPTION

Hereinafter, an image sensor and a method for manufacturing the same according to an embodiment will be described with reference to accompanying drawings.

In the description of embodiments, it will be understood that when a layer (or film) is referred to as being ‘on’ another layer or substrate, it can be directly on another layer or substrate, or intervening layers may also be present. Further, it will be understood that when a layer is referred to as being ‘under’ another layer, it can be directly under another layer, or one or more intervening layers may also be present. In addition, it will also be understood that when a layer is referred to as being ‘between’ two layers, it can be the only layer between the two layers, or one or more intervening layers may also be present.

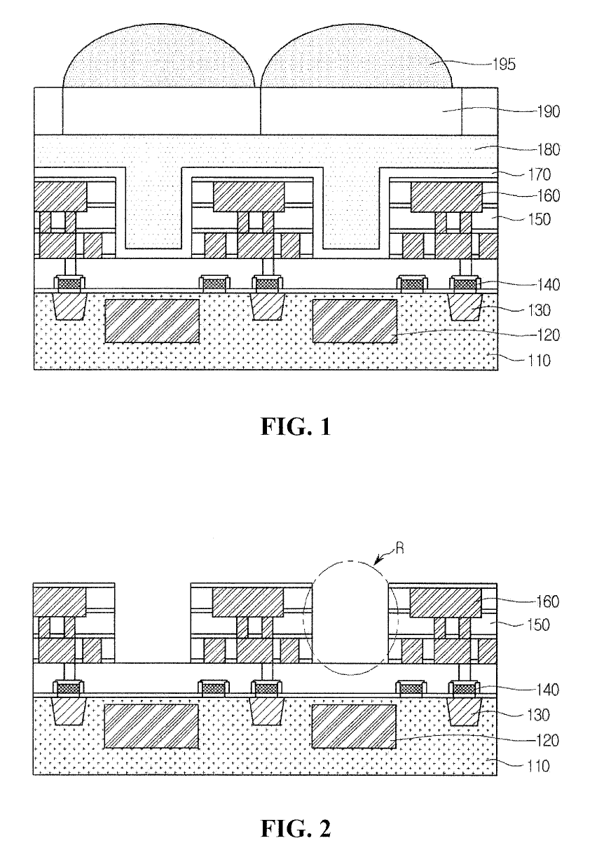

Referring to FIG. 1, an image sensor according to an embodiment can include a photodiode 120 formed on a substrate 110, an interlayer dielectric layer 150 and a metal interconnection 160 formed on the substrate 110, the metal interconnection 160 connecting to a variety of structures on the substrate 110 and the interlayer dielectric layer 150 having a recess structure R (see FIG. 2) which is obtained by selectively removing a predetermined portion of the interlayer dielectric layer 150 corresponding to the photodiode 120; a clad layer 170 formed on the interlayer dielectric layer 150; and a core layer 180 formed on the clad layer 170.

The clad layer 170 and the core layer 180 can cause a total reflection of light. By reflecting light, crosstalk can be inhibited and the sensitivity of the image sensor can be improved.

The clad layer 170 can be formed along the surface of the interlayer dielectric layer 150 including the sides and bottom of the recess structure R (see FIG. 2), and the core layer 180 can fill in the recess structure R.

According to an embodiment, the core layer 180 has a refractive index higher than that of the clad layer 170 such that light incident into the core layer 180 is totally reflected from the boundary surface between the core layer 180 and the clad layer 170. Accordingly, problems caused by crosstalk can be inhibited.

In certain embodiments, the substrate 110 can be formed with an isolation layer 130 and a transistor 140. The metal interconnection 160 can be electrically connected to the transistor 140. The image sensor can also include a color filter layer 190 and a micro-lens 195.

Hereinafter, a method for manufacturing the image sensor according to an embodiment will be described with reference to FIGS. 2 to 5.

Referring to FIG. 2, an active area can be defined on the substrate 110 by forming an isolation layer 130. The isolation layer 130 can be formed, for example, through a shallow trench isolation (STI) process or a local oxidation of silicon (LOCOS) process.

A photodiode 120 and transistor 140 can be formed on the substrate 110. According to an embodiment, 1Tr-type, 2Tr-type, 3Tr-type, 4Tr-type or 5Tr-type image sensor can be formed. The type is labeled according to the number of transistors formed in each unit pixel. For example, the 3Tr-type image sensor includes one photodiode and three transistors (a reset transistor, a drive transistor, and a select transistor), and the 4Tr-type image sensor includes one photodiode and four transistors (a transfer transistor, a reset transistor, a drive transistor, and a select transistor).

Next, a metal interconnection 160 and interlayer dielectric layer 150 can be formed on the substrate 110 having the photodiode 120 and transistor 140. The metal interconnection 160 can be a multi-layer metal interconnection. In addition, the interlayer dielectric layer 150 and metal interconnection 160 can be formed in plurality to provide signal and power paths.

The interlayer dielectric layer 150 can also have a multilayer structure. In one embodiment in forming a multilayer structure, a first interlayer dielectric layer can be formed, and then a light shielding layer (not shown) to inhibit light from being incident into a region other than the photodiode 120 can be formed. Then, another interlayer dielectric layer can be formed on the resultant structure.

In a further embodiment, a protective layer (not shown) can be formed on the interlayer dielectric layer 150 to protect devices from moisture and scratch.

The interlayer dielectric layer 150 in a region corresponding to the photodiode 120 can be selectively removed to form the recess structure R. For embodiments having the interlayer dielectric layer 150 formed in plurality, each of the plurality of layers can be removed. In other embodiments having the interlayer dielectric layer 150 formed in plurality, at least one layer can be removed to form the recess structure R.

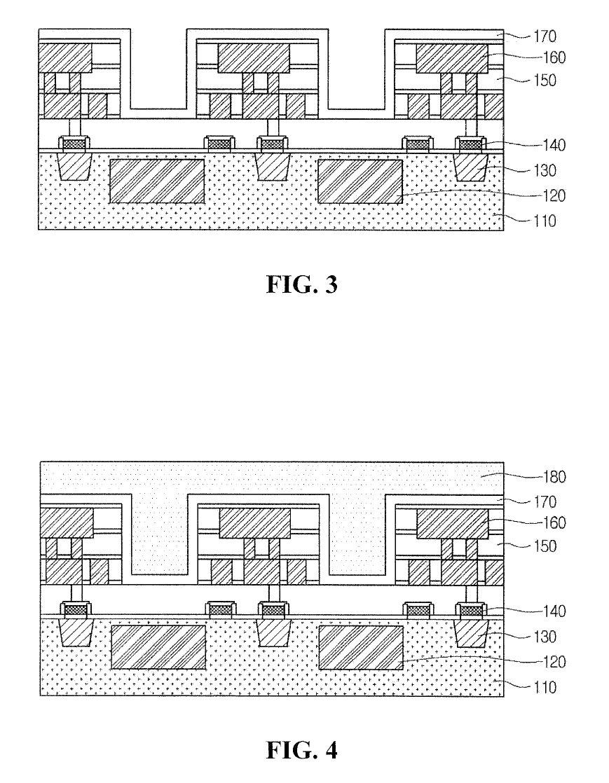

Subsequently, referring to FIG. 3, a clad layer 170 can be formed on the interlayer dielectric layer 150, including in the recess structure R.

The clad layer 170 can be formed along the entire surface of the interlayer dielectric layer 150 having the recess structure R.

In an embodiment, the clad layer 170 can include optical fiber or materials used to form optical fibers. In one embodiment, the clad layer 170 can have an oxide film. In a specific embodiment, the clad layer 170 can include silicon dioxide (SiO₂).

Referring to FIG. 4, a core layer 180 can be formed on the clad layer 170. The core layer 180 can be formed to fill in the recess structure R.

In an embodiment, the core layer 180 can include optical fiber or materials used to form optical fibers. In one embodiment, the core layer 180 can have an oxide film such as SiO₂.

The core layer 180 can have a refractive index higher than that of the clad layer 170.

This can be achieved in certain embodiments by increasing the density of impurities of the core layer 180 as compared with the density of impurities of the clad layer 170.

For example, when forming the core layer 180, the density of the impurities of the core layer 180 can be increased by employing a process temperature lower than the process temperature used to form the clad layer 170.

According to an embodiment, an optical fiber structure can be employed within the recess structure R in order to inhibit light loss and crosstalk at the side surfaces of the recess structure R.

In the optical fiber structure, the refractive index of the core layer 180 transmitting light is less than the refractive index of the clad layer 170, which serves to block light from being transmitted to the outside thereof. Therefore, the light incident into the core layer 180 is totally reflected from the boundary surface between the core layer 180 and the clad layer 170 having different refractive indexes.

According to an embodiment, when an oxide film such as SiO₂ is used as the material of the optical fiber forming the core layer 180 and the clad layer 170, the core layer 180 and the clad layer 170 can be easily obtained through an existing semiconductor inter-metal dielectric (IMD) manufacturing process.

In a specific embodiment, a pure oxide film is formed on the side surface of the recess structure R to serve as the clad layer 170, and a normal oxide film is filled in the recess structure to serve as the core layer 180, thereby forming conditions for total reflection at the boundary surface between the clad layer 170 and the core layer 180.

Accordingly, it is possible to inhibit the degradation of sensitivity caused by the light leakage of the side surface of the recess structure R, and reduce crosstalk caused by an influence exerted by the leaking light on peripheral pixels.

In a further embodiment, the core layer 180 can be planarized.

Meanwhile, since light is incident onto a portion of the clad layer 170, which exists between the core layer 180 and the photodiode 120, with a specific angle at which total reflection of the light does not occur, an additional etch process is not necessary to remove the portion of the clad layer 170.

However, in certain embodiments, an etch process can be additionally performed in order to remove the clad layer 170 remaining between the core layer 180 and the photodiode 120 before forming the core layer 180 on the clad layer 170.

In addition, the etch process can also be performed to remove the clad layer 170 existing on the metal interconnection 160 and interlayer dielectric layer 150 other than in the recess structure R.

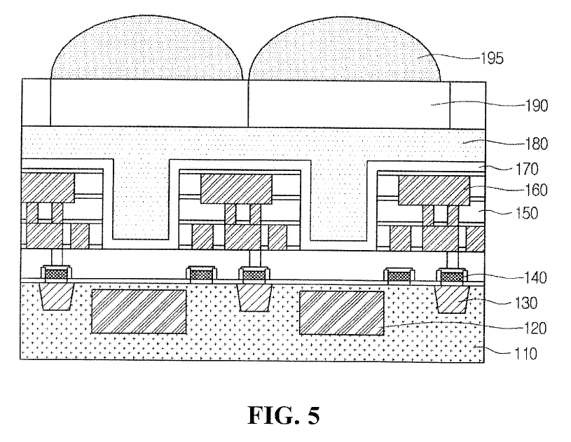

Referring to FIG. 5, a color filter layer 190 can be formed on the core layer 180.

For example, a dyeable resist can be coated on the core layer 180, and an exposure and development process can be performed with respect to the resultant structure. This process can be repeated to form red (R), green (G), and blue (B) color filters in the color filter layer 190 to filter light according to corresponding wavelengths.

Then, a planarization layer (not shown) can be formed on the color filter layer 190 in order to ensure planarity for the adjustment of a focal length and the formation of a lens layer.

A micro-lens 195 can be formed on the color filter layer 190 (or planarization layer) in order to condense light towards the photodiode 120.

In the image sensor and the method for manufacturing the same according to embodiments of the present invention, a clad layer and core layer can be formed between a surface to which external light is incident and a photodiode. The clad layer and core layer can be used to cause total reflection of light and reduce error caused by crosstalk between pixels.

In addition, in the image sensor and the method for manufacturing the same according to an embodiment, the clad layer and the core layer can be formed to cause total reflection of light, so that sensitivity can be increased.

In addition, according to an embodiment, pixels can be isolated from each other using the clad layer and the core layer without additional photo and etch processes.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the components and parts and/or arrangements of the subject combination arrangement within the scope of the disclosure, the drawings and the appended claims. In addition to variations and modifications in the components parts and/or arrangements, alternative uses will also be apparent to those skilled in the art.

What is claimed is:

1. An image sensor comprising:
a substrate including a photodiode;
a metal interconnection and interlayer dielectric layer on the substrate, wherein the interlayer dielectric layer has a recess structure in a region corresponding to the photodiode;
a clad layer on the interlayer dielectric layer; and
a core layer on the clad layer.

2. The image sensor according to claim 1, wherein the clad layer is provided along side and bottom surfaces of the recess structure of the interlayer dielectric layer.

3. The image sensor according to claim 1, wherein the clad layer is provided only along side surfaces of the recess structure of the interlayer dielectric layer.

4. The image sensor according to claim 1, wherein the core layer completely fills in the recess structure.

5. The image sensor according to claim 1, wherein the core layer has a higher refractive index than the clad layer.

6. The image sensor according to claim 1, wherein the core layer has a higher density of impurities than the clad layer.

7. A method for manufacturing an image sensor, comprising:
providing a substrate including a photodiode;
forming a metal interconnection and an interlayer dielectric layer on the substrate;
forming a recess structure in the interlayer dielectric layer by selectively removing a portion of the interlayer dielectric layer in a region corresponding to the photodiode;
forming a clad layer on the interlayer dielectric layer having the recess structure; and
forming a core layer on the clad layer.

8. The method according to claim 7, further comprising forming a color filter layer on the core layer.

9. The method according to claim 7, further comprising etching a portion of the clad layer such that the clad layer is provided only in the recess structure of the interlayer dielectric layer.

10. The method according to claim 7, further comprising etching a portion of the clad layer such that the clad layer is provided only along side surfaces of the recess structure of the interlayer dielectric layer.

11. The method according to claim 7, wherein forming the core layer on the clad layer completely fills the recess structure with the core layer.

12. The method according to claim 7, wherein the core layer has a higher refractive index than the clad layer.

13. The method according to claim 7, wherein the core layer is formed having a higher density of impurities than the clad layer.

14. The method according to claim 7, wherein the core layer is formed under a lower process temperature than the clad layer.

15. The method according to claim 7, wherein forming the clad layer comprises forming a pure oxide film on the interlayer dielectric layer including on the recess structure.

16. The method according to claim 15, wherein forming the core layer comprises forming a normal oxide film.

17. The method according to claim 16, wherein forming the normal oxide film comprises forming an oxide layer at a lower process temperature than that used during the forming of the clad layer.
